(19) United States
(12) Patent Application Publication
(10) Pub. No.: US 2008/0278115 A1
(43) Pub. Date: Nov. 13, 2008

(54) Battery Management System

(76) Inventor: Mark Huggins, West Lothian (GB)

Correspondence Address: KED & ASSOCIATES, LLP, P.O. Box 221200, Chantilly, VA, 20153-1200, US

(21) Appl. No.: 11/815,430

(22) PCT Filed: Feb. 6, 2006
(86) PCT No.: PCT/GB2006/000385

§ 371 Date: May 19, 2008

(30) Foreign Application Priority Data
Feb. 4, 2005 (GB) 0502274.4

(51) Int. Cl. H01M 10/48; H02J 7/00; G01R 31/36

(52) U.S. Cl. 320/134; 320/136; 340/636.1; 320/150

(57) ABSTRACT

A battery management system for use with one or more cells comprising the system having one or more battery monitor and programmable logic which is connected to the one or more battery monitor to modify its battery operation and report battery status. The programmable logic may be configured to analyse physical data relating to the effect of temperature on battery capacity and/or the effect of temperature on battery self discharge current. Implementation is applicable to all electrical energy storage systems that comprise series or parallel connected electro chemical storage elements. This includes Super or Ultra Capacitor's, fuel cells, NiMH, NiCd, Pb & Lithium Chemistry battery packs.

The present invention relates to battery management systems, to their implementation in Electronic Integrated Circuits, and more particularly to large scale integration techniques commonly known as System On Chip or System Level Integration.

In the field of battery management, it is highly desirable to monitor and/or control a number of parameters that affect battery performance. For example, a battery management system might include some of the following functionality:

State of Charge (SoC) measurement for determining the amount of remaining stored energy;

State of Health (SoH) measurement for determining the battery life expectancy;

Battery protection monitoring to ensure safe battery operation;

Charge Control for regulation of charging current and voltage; and

Cell Balancing to ensure maximum energy is stored and delivered without activating protection circuitry.

Presently many different electronic circuits are employed to provide the above described functionality. Current industry implementation makes use of up to seven integrated circuits to provide a total solution with only a few devices contained within the battery pack. Cell balancing, charger, and some data processing are housed within the host system.

Semiconductor manufacturers have developed specific electronic integrated circuits that provide one or more of these features in an attempt to reduce cost and minimize solution size. Such examples of devices are Fuel Gauging IC's that provide SoC, Protection IC's that monitor the safe operation of the battery, Passive Cell Balancer IC's that ensure safe charging of multiple series connected battery cells, and Charger IC's that control the battery's charger unit. It therefore takes a number of integrated circuits and additional discrete circuitry to build a complete battery management system.

Problems that are not currently addressed are:

Accurate determination and compensation of battery self discharge current;

Compensation of SoC for battery operational temperature; Cell balancing during discharge;

Accurate SoH (State of Health) determination; and

Application of battery management to large Cell stacks (greater than 8 series or parallel connected cells).

Passive Cell Balancing

A single cell Li-Ion battery provides a nominal output voltage of around 3.7V and has a narrow range of safe operation of between 3V and 4.2V. Should the cell voltage drift outwith this safe zone, through over discharge or over charging, the Li-Ion cell will be irreparably damaged and under certain circumstances there is risk of catastrophic failure resulting in fire and or explosion.

An internal protection circuit as described earlier prevents the cell from being over charged or discharged.

In multi-cell battery packs, cells are connected in series to provide a greater output voltage for use in applications that require a greater energy capacity such as lap top computers and electric vehicles. Each cell has slightly different electrical characteristics due to variations in assembly and chemistry. The protection circuit must act on the lowest and/or highest cell voltage in the multi-cell pack. This means that battery packs can be disabled for just a single discharged cell, thus preventing further energy being released, or a single overcharged cell preventing full charge of the battery pack. This problem significantly reduces the available charge from a multi-cell battery.

The objective of cell balancing is to compensate for these variations in cell electrical characteristics such as impedance and capacity by ensuring that each ‘series’ connected cell operates with the same cell voltage and within an acceptable tolerance. Cell balancing maximizes available charge in series connected multi-cell battery packs and increases life expectancy through reduction in charging cycles.

Passive:

Passive cell balancing switches a resistor across a high voltage cell to remove charge from it and pass it onto the lower cell/cells. Another possible approach would be to use a shunt regulator across each cell this would remove the need for the resistor with all cell voltage being supported by the shunt pass transistor. Both methods have two problems; firstly they both dissipate energy, secondly their only use is during the charging cycle as it would lessen battery capacity and shorten life during discharge cycle due to the additional dissipation. Current Li-Ion battery management integrated circuits that incorporate cell balancing utilize the passive approach examples being Xicor's X310 series and Texas Instruments bq29311.

It is an object of the present invention to provide a complete battery management system. It is a further object of the invention to implement the battery management system on a single Application Specific Integrated Circuit or by using several integrated circuits with or without further discrete circuitry.

In accordance with a first aspect of the present invention there is provided a battery management system for use with one or more cells comprising a battery, the battery management system comprising:

one or more battery monitoring means; and programmable logic;

wherein the programmable logic is connected to the one or more battery monitoring means to modify its battery operation and report battery status.

Preferably, the battery monitoring means reports battery status through a communication bus to an external host.

Implementation is applicable to all electrical energy storage systems that comprise series or parallel connected electro chemical storage elements. This includes but is not limited to Super or Ultra Capacitor's, fuel cells, NiMH, NiCd, Pb & Lithium Chemistry battery packs.

Implementation of programmable logic enables the invention to be configured for a variety of battery chemistries.

Preferably, the battery monitoring means is provided with data acquisition means to record battery performance parameters.

Preferably, the programmable logic is configured to analyse data received from the one or more battery monitoring means and to modify the operation of the battery in response to said data.

Preferably, data acquisition means is placed across each cell of the battery to collect data from said cell.

Optionally, a data acquisition device is configured to collect data from a plurality of cells.

Preferably, the programmable logic is configured to analyse physical data.

Preferably, the programmable logic is configured to analyse physical data relating to the effect of temperature on battery capacity and/or the effect of temperature on battery self discharge current.

Preferably, the programmable logic is configured to derive the actual state of charge at any operational temperature.

Preferably, the programmable logic contains one or more look-up tables and/or algorithms.

Preferably, the programmable logic comprises a digital microprocessor and digital memory.

Preferably, the programmable logic comprises a digital means of communication with internal and external systems and the ability to report battery status and provide external control of a battery.

Preferably, the programmable logic is embedded in the battery management system.

Preferably, the battery monitoring means comprises state of charge measurement means.

Preferably, the battery monitoring means comprises state of health measurement means.

Preferably, the battery monitoring means comprises battery protection means.

Preferably, the battery protection means comprises switching means to control current flow from a power source.

Preferably, the battery monitoring means comprises charging control means.

Preferably, the battery monitoring means comprises active cell balancing control means enabling transfer of energy from strong to weak cells.

Preferably, the active cell balancing control comprises a switched mode converter, attachable to a primary energy source and capable of moving energy from the primary energy source to one or more cells depending upon the respective energy requirements of the cells. The primary energy source can be a battery or an external power supply.

Preferably, the programmable logic is adapted to operate temperature control means.

Preferably, the temperature control means comprises heating means to warm the cells.

The primary energy source can be external to the battery pack in charge mode.

Preferably, the primary energy source can be derived from the battery pack in active cell balancing mode

Preferably, the active cell balancing circuitry can operate as an integral charger.

Preferably, the active cell balancing circuitry can operate as a sulphation removal system when used in a Pb (lead acid) battery stack.

This is a result of the the ability of the active cell balancing circuitry to deliver current pulses.

A Flyback topology can be used as a switched mode converter.

The type of switched mode converter is not limited to flyback and can comprise other converter topologies.

The use of a Flyback Switched Mode Converter in both discontinuous and continuous mode is an effective energy transfer device for cell balancing and cell charging as all outputs track.

Preferably, the Flyback switched mode converter is provided with one or more synchronous output or secondary rectifiers.

The use of synchronous rectifiers improves energy conversion efficiency and can better steer energy to the appropriate weak cell.

Optionally, the Flyback switched mode converter is provided with one or more output or secondary rectifier diodes.

Preferably, a switched magnetic or capacitive converter may be configured to actively transfer energy from strong cells to weak cells within the battery pack.

Preferably, the battery management system is provided with self discharge current measurement means.

Preferably, the self discharge measurement means comprises a current oscillator which can be coupled to a battery when the battery is in sleep mode, the current oscillator having a temperature coefficient that corresponds to the temperature coefficient of the battery.

Preferably the battery management system is provided with means for disabling the battery during transit, said means being provided as an instruction from the programmable logic.

In accordance with a second aspect of the invention there is provided a battery management system of the first aspect of the invention incorporated in an application specific integrated circuit.

In accordance with a third aspect of the invention there is provided a battery management system of the first aspect of the invention incorporated in a discrete printed circuit board.

In accordance with a fourth aspect of the invention there is provided a battery pack containing a battery and a battery management system of the first aspect of the invention wherein the battery management system is embedded in the battery pack.

Preferably, application to a large cell stack can be implemented through modules that comprise individual DC/DC converters, all monitoring, communication and logic functions. Each cell in the stack is connected to its own individual cell module.

The present invention will now be described by way of example only, with reference to the accompanying drawings in which:

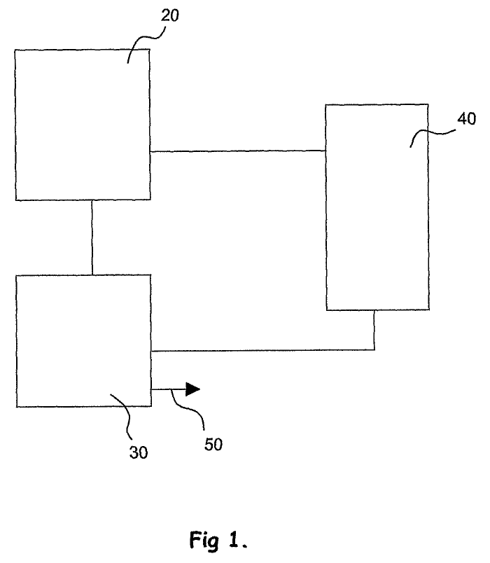

FIG. 1 is a schematic diagram of an example of the present invention;

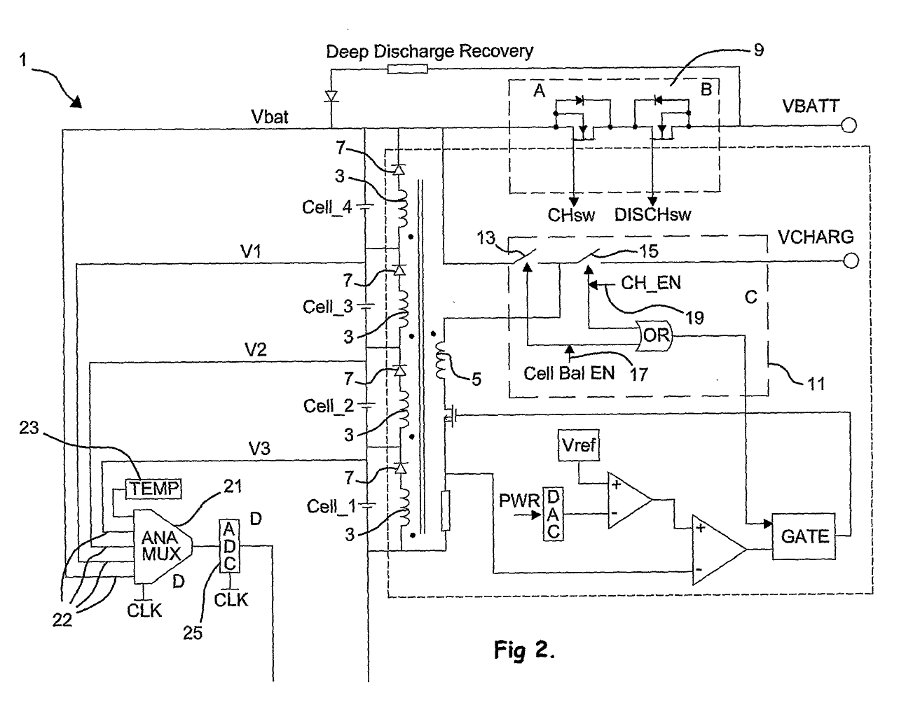

FIG. 2 is a circuit block diagram of a first embodiment of a battery management system in accordance with the present invention;

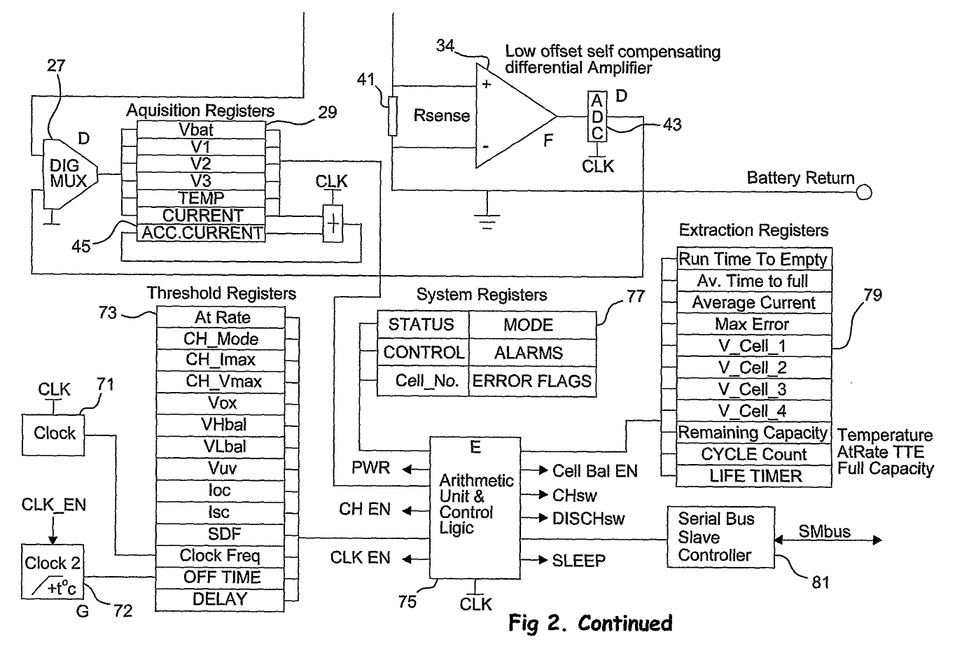

FIG. 3 is circuit block diagram of a switched mode converter used in a second embodiment of the present invention;

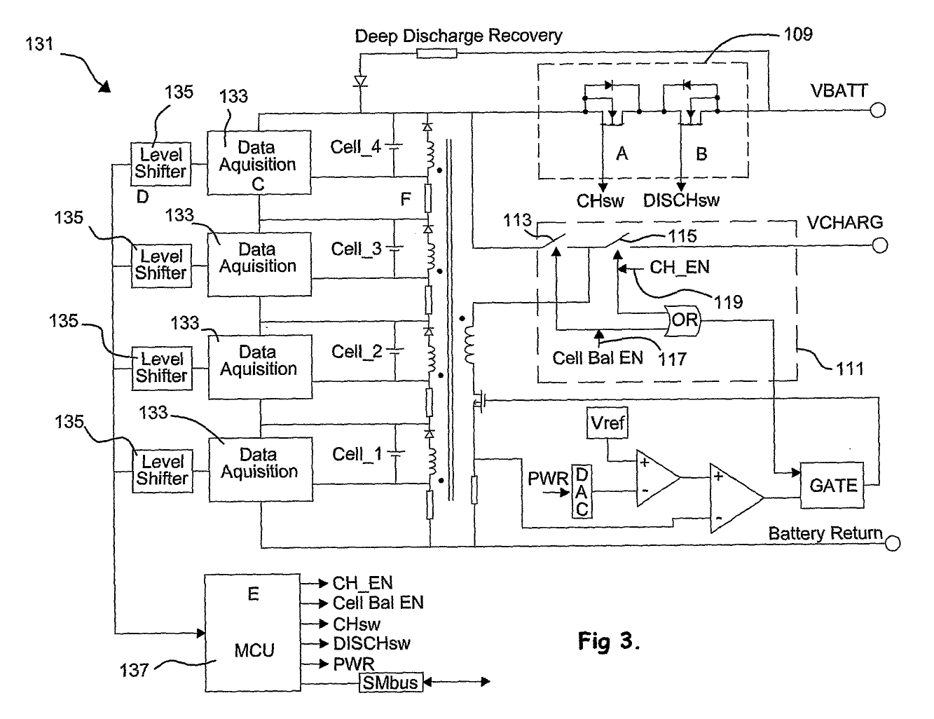

FIG. 4 is a circuit block diagram of a data acquisition device suitable for use in an embodiment of the present invention;

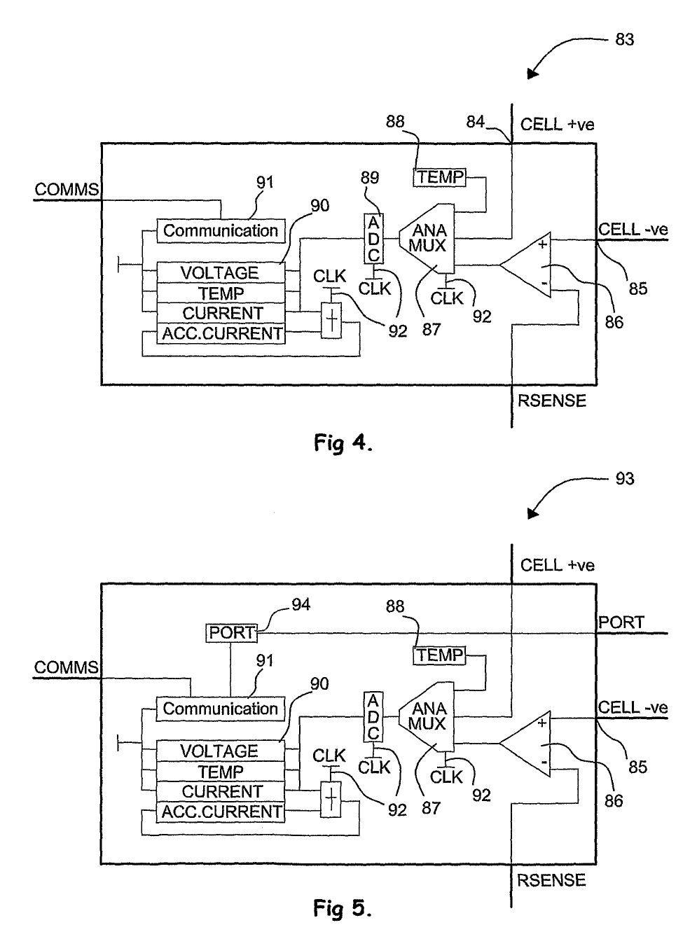

FIG. 5 is a circuit block diagram of a data acquisition device suitable for use in an embodiment of the present invention;

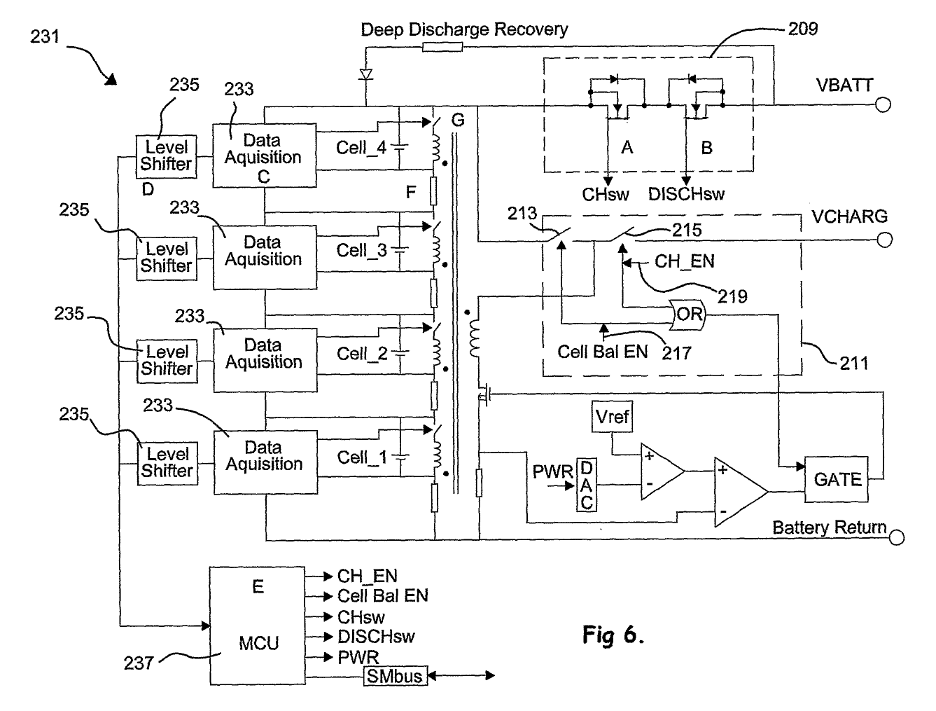

FIG. 6 is a circuit block diagram of a second embodiment of the present invention;

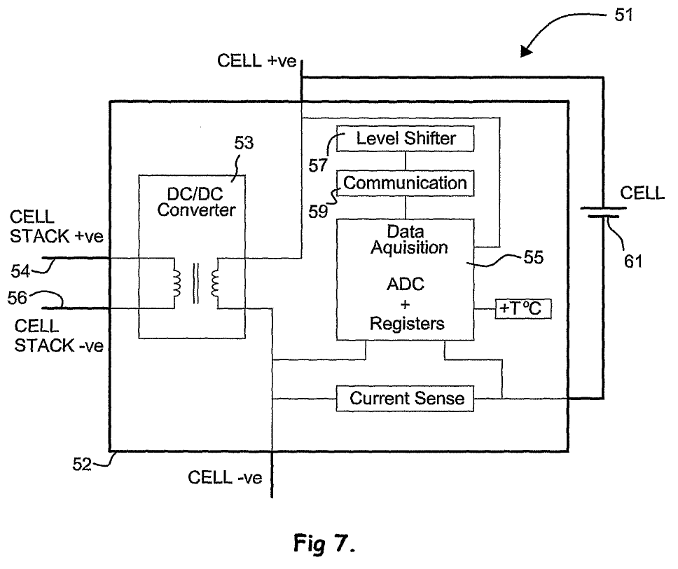

FIG. 7 is a circuit block diagram of a digital processor and controller for use in an embodiment of the present invention with a large number of series connected cells;

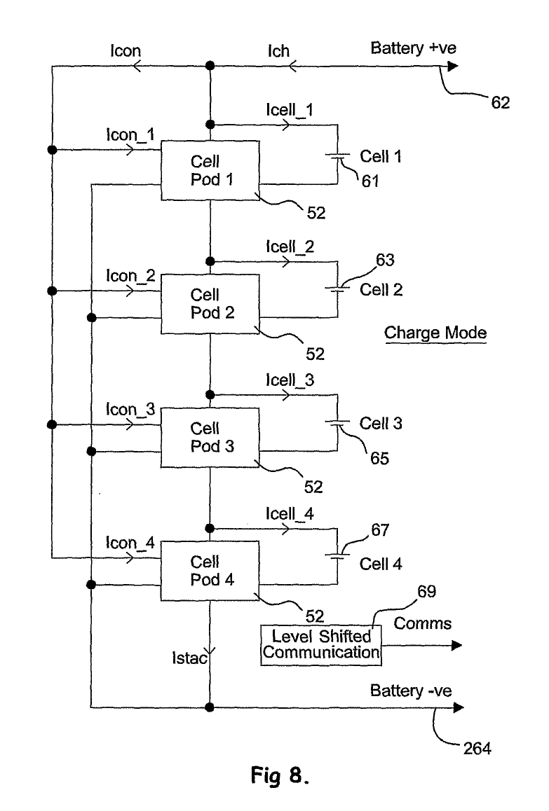

FIG. 8 is a circuit block diagram showing the configuration of modules described in FIG. 6 where the circuit is in charge mode;

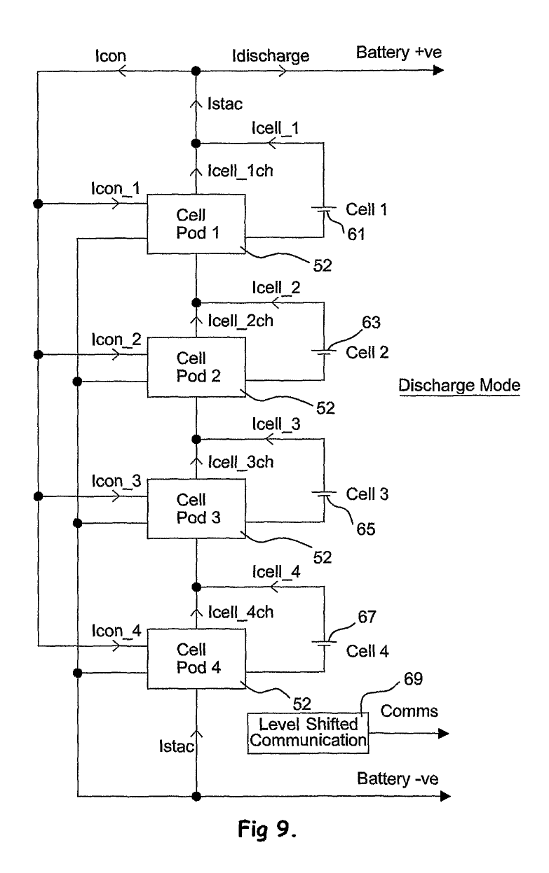

FIG. 9 is the circuit block diagram of FIG. 8 in discharge mode; and

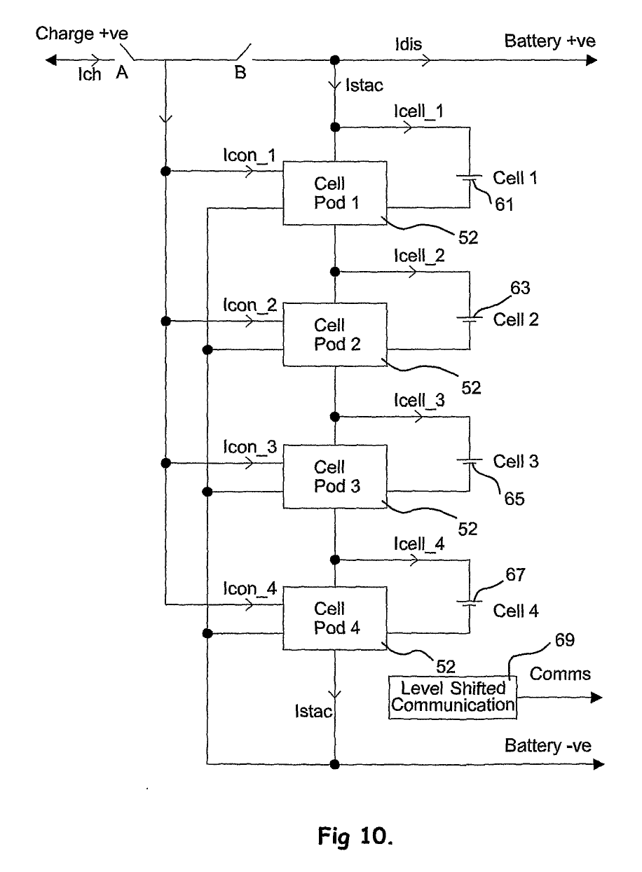

FIG. 10 is the circuit block diagram of FIG. 8 implemented with a constant voltage charger.

As shown in FIG. 1, the present invention incorporates battery monitoring means 20 such as active cell balancing control and status reporting, SoC measurement and reporting, SoH measurement and reporting, Protection control and status reporting, Charging control and reporting.

These battery monitoring means are programmable through the implementation of programmable logic 30 as an embedded digital microprocessor and digital memory. The battery management system is able to communicate so with an external host through the implementation of a serial or parallel wired bus or through a wireless communication link. The programmable logic is also able to communicate with the battery 40.

Implementation of a digital microprocessor and digital memory enables the present invention to be configured for multiple battery chemistries. In addition, the digital microprocessor and digital memory enables processing of captured data to compensate for a wide variety of physical processes not currently considered in the state of the art. In particular algorithms or look up tables can be used to compensate for the effect of temperature on battery capacity and for the effect of temperature on battery self discharge current. Algorithms are also used to establish cell aging from variation in complex cell impedance coupled with depth of discharge history. The complex and static impedance being derived from the measurements made by the data acquisition modules.

An example of the present invention is shown in FIG. 2. The implementation of a Flyback Switched mode power supply either operating in the discontinuous or continuous mode offers a source of charge current for each series connected cell within the battery. Multiple secondary windings on a single coupled inductor 5 enable the sharing of energy that is delivered to the coupled inductor through the primary inductor winding 5. The primary energy source can be from an external charge source or if connected to the battery output from the battery itself.

Implementation can also comprise individual switch mode power supply converters without coupled secondary windings.

When connected to the battery output the circuit is configured for Active Cell Balancing. In this mode energy is taken from the battery pack and delivered to the weakest (lowest charge state) cell effectively transferring energy from higher capacity cells. into lower capacity cells to enable the maximum energy to be withdrawn from the battery pack. Without Active Cell Balancing the battery's protection circuit would turn off the battery output when the lowest charged cell was depleted even though energy remained in higher capacity cells.

An enhancement of the Active Cell Balancer circuit shown as a Flyback switched mode power supply in FIG. 1 is to place individual data acquisition devices across each cell as shown in FIG. 3. This enables greater accuracy of capacity determination in accommodating energy lost through cell balancing. It is to be noted that Active Cell balancing provides greater accuracy due to its significantly higher efficiency than Passive Cell balancing. This configuration can also report individual cell absolute and relative capacities as they age so providing useful service information. Typical data acquisition devices are shown in FIGS. 4 and 5.

The data acquisition device 83 of FIG. 4 comprises inputs from a cell 84, 85 a low offset compensating differential amplifier 86 connected to an analogue multiplexer 87 which also has a temperature sensor 88 connected to its input. The analogue to digital converter 89 provides the input to register 90 and communications means 91. A synchronising clock input 92 is also provided.

An additional enhancement to the Active Cell Balancer shown as a Flyback converter in FIGS. 2 and 3 is to replace all output diodes with synchronous rectifiers (FIG. 6). In this embodiment the microprocessor can select which synchronous rectifier to activate in order to better steer energy into the weakest cell without energy escaping into higher charged cells which reduces overall efficiency. In this embodiment the data acquisition device 93 has, in addition to those features shown in FIG. 4, a control port 94 that activates the synchronous rectifier (FIG. 5).

A four cell battery management system incorporating active cell balancing is described in FIG. 2, 3 and 6.

The system contains six functional blocks The battery protection block that protects the battery from excessive charge and discharge.

The charger block that replenishes charge once the battery is discharged.

The data acquisition block that acquires state of battery (voltage, current, temperature, capacity) information.

The coulomb counter block that accurately determining the available capacity of the battery (fuel gauge).

The digital processor and digital bus communication block that processes data and hosts communications.

The Cell Balancing used to maximize the available charge in series connected multi-cells.

The Active Cell Balancing unit can be configured to act as the charger thereby eliminating the need for an additional charger circuit.

Battery Protection

Referring to FIG. 2 battery protection 9 is afforded through two power switches referenced A and B. These two switches are controlled by logic that operate each switch depending on the operating condition sensed by the data acquisition circuitry. The two switches enable either full charge/discharge (two way current flow), charge only (one way current flow into battery), discharge only (one way current flow out of the battery) and finally in a fault condition both switches are off enabling no current to flow into or out of the battery.

It is to be noted that Li-Ion batteries have a very narrow window of safe operation and if subject to operating conditions outwith this window extensive damage can result to the Li-Ion cell/battery and in extreme situations there is risk of excessive heat/explosion. Battery protection is therefore for Li-Ion cells/batteries.

The conditional state of protection circuitry and operating mode can be relayed to the host system by the digital bus communication link between battery pack and host system.

Battery Charger

Referring to FIG. 2 the battery charger 11 is represented by the block identified as reference C. The purpose of the charger block is to replenish the battery charge from a variety of power sources such as a mains outlet block, or vehicle 12V/24V socket. The charger block is under control of the internal data processor and the host system controller via the digital bus communication link between battery pack and host system.

The Charger block is function performed by the Active Cell Balancer block. Two switches controlled by CH_EN 19 and CellBalEN 17 select which mode is appropriate. The two switches are never on at the same time.

The charger can operate in a number of modes accommodating a variety of different battery cell chemistries. These modes include constant current followed by constant voltage and float charging. A detailed description of operation now follows:

Data Acquisition

The purpose of the data acquisition circuitry is to provide measurements of all the batteries vital performance parameters such as cell voltage, current flow and temperature. These parameters are analogue so they need to be sensed (21, 22) and then converted into digital signals 25 before being handed over to the digital processor. Two 12 bit Analogue to Digital Converters 25, ADC's, are used. The inputs 22 to the ADC's are multiplexed 21 to save on operating current and circuit area. One analogue multiplexer 21 and one digital multiplexer 27 are used. An acquisition register 29 is provided to hold the acquired data for further processing. All this circuitry is represented by the reference D in FIG. 2.

The analogue and digital multiplexers are programmable to accommodate different numbers of series connected cells. The embodiment described in FIG. 3 and 6 show each cell having its own data acquisition device (133,233,135,235) each reporting to the main micro controller through a common serial communication bus. This improves the accuracy of data collected specific to each individual cell.

Coulomb Counter

To accurately determine available capacity of battery (fuel gauge) the current into and out of the battery is sensed and integrated (accumulated). The charge is counted going into the battery and the charge is counted leaving the battery the difference between the two counts is the estimated remaining battery capacity. An ultra low offset self compensating differential amplifier 34, FIG. 2 reference F, senses the voltage across the current sense resistor 41. The maximum voltage corresponding to maximum current will be around +/−100 mV. The output of the differential amplifier is then converted to a digital value by an ADC and placed in the acquisition register for later processing by the arithmetic unit and accumulated current register. Current is integrated by the cumulative addition of sampled current in the ACC. CURRENT register 45. The output of the current ADC is signed in 2's complement to enable subtraction for discharge.

In the embodiment described by FIGS. 3 and 6 each cell has its own Coulomb Counter to improve accuracy of measurement and provide additional state of health information.

Digital Processor and Digital Bus communication

A digital signal processor is required to control system operation, collate acquired data, process data, communicate data with host system, and accept system control commands from host system via the communication digital bus.

The digital processor and digital bus communication functionality of FIG. 2 provide the programmable logic functions which operate upon the data acquired relating to cell performance. A clock 71 and clock enable 72 are provided along with a threshold register which contains threshold valves of many of the measurable physical parameters of a cell such as Ch_Imax (Charge Current Maximum). The arithmetic unit and control logic 75 is programmable in a manner selected by the user depending upon for instance the physical properties of the cells in the battery.

System register 77 which controls status and mode of the system as well as an extraction register 79 and communications (bus 81) are also shown.

The programmable logic is programmed to optimize battery performance in response to changes in battery performance identified through acquired data.

Active Cell Balancing

The present invention uses active cell balancing. Active cell balancing makes use of switching capacitors or magnetic circuits to balance each cell voltage. The active approach can be applied in both the charge and discharge cycle furthermore the efficiency of conversion is greatly increased. There are potentially many different types of active cell balancing circuits, some of the simplest make use of capacitors that are switched across each cell in rotation. The capacitors transfer charge to and from each cell to balance their respective voltages. As a consequence of the size of capacitors and switching frequency required this configuration works best for low capacity batteries.

Other possible active cell balancing schemes can make use of magnetic switching circuits such as the Buck and Flyback topologies. The Flyback approach is simple to implement and has the inherent ability to distribute energy without the need for any complex control circuitry. However, the design of the Coupled Inductor is important because all leakage inductances must balance within limits to enable accurate charge distribution.

Given the application tolerances for Li-Ion the Flyback approach has been adopted in the embodiment of the invention shown in FIGS. 2 and 3 and 6.

FIG. 2 shows a four cell system. However, the digital processor and controller can be made flexible to accommodate a defined maximum number of cells. The cell number register can be written to via the serial bus to define the number of cells for any given application. This data register is then used by the controller to configure all Analogue and Digital multiplexers and data registers to control a specific number of cells for that programmed application. Though the maximum number of series connected cells is envisaged to be no more than eight in this embodiment. For application to a greater number of series connected cells the embodiment described by FIGS. 7 and 8 and 10 would enable systems to be built that would support application to heavy industrial devices such as electric vehicles and standby battery banks that generally require terminal voltages exceeding 300V.

The cell balancing circuit activation can be enabled outside of two programmable thresholds VHbal and VLbal. This will prevent the cell balancing circuitry being active during most operating conditions and hence save on battery life. Only when any cell voltage is higher than the VHbal or lower than the VLbal thresholds will the cell balancing circuitry be active.

Accurate self discharge estimate: When the battery is lying idle with no current being drawn from it there exists a low internal self discharge current that changes with cell temperature and cell voltage. If the appliance is switched off for an extended period of time the indicated remaining capacity will be in error due to the extended period of self discharge. The present invention provides a means of estimating the self discharge current during power down and thus provides a far more accurate indication of remaining capacity when the appliance is turned on after an extended power off period.

The present invention uses an ultra low current oscillator (reference G), that operates when the battery is in sleep mode. The oscillator has a strong temperature coefficient that corresponds with that of the battery self discharge temperature profile. The count obtained from the sleep counter is processed with the capacity register on recovery from sleep mode to provide an accurate estimate of remaining capacity.

The ultra low current oscillator prevents further drain on battery during sleep mode and to match the temperature coefficient to that of the battery cell discharge profile.

Safe Transportation and Storage: Use of internal protection circuit to disable battery pack when in transportation, storage or host demand. The digital serial bus enables commands to be sent to the battery management system controller to disable the battery on demand.

Temperature Variation of State of Charge: This effect is particularly acute for Lithium based cell chemistries. The available capacity from a cell can significantly reduce as temperature falls. The full capacity is restored upon temperature recovery. The implementation of an embedded digital microprocessor and digital memory enables acquired capacity data to be processed using look up tables or algorithms to compensate for this temperature affect.

FIG. 8 shows the configuration of modules 52 described in FIG. 7 to implement a full active cell balancing system for a stack of four cells (61,63,65,67). The modular construction permits as many series connected cells as the rated isolation voltage of the DC/DC converter and communication system can tolerate. FIG. 8 shows a battery system being supplied by a Constant Current Constant Voltage (CCCV) charger connected across Battery +ve and Battery −ve terminals. At the start of the charge cycle a constant current, Ich, is supplied to the cell stack. Current is diverted away from the cell stack, Istac, by CELL Pod DC/DC converters, Icon, to support cells that have lower voltages. This reduces the rate at which higher voltage cells charge and increases the rate at which lower voltage cells charge. It is through this mechanism that each cell voltage may be balanced during the charge cycle. This implementation relies on their being a constant current charge source which is valid for Lithium Ion and many other cell chemistries.

In the discharge cycle as shown in FIG. 9 current is taken from the cell stack by DC/DC converter/converters to boost the cell voltage/voltages of cells that have a lower voltage. In this embodiment Istac>=Idischarge (Istack=Icon+Idischarge) though individual cells of low voltage will have significantly lower current than Istack with the DC/DC converter supporting Istack though bypassing each low voltage cell. For low voltage cells Icell_x<Istack with Icell_xch+Icell=Istack.

FIG. 10 shows implementation to constant voltage chargers as used with Lead Acid cell technology. In this embodiment all charge current is passed through the cell DC/DC converters. Each cell converter has direct control over its connected cell charge rate and so can regulate its cell voltage at an appropriate level during charge cycle. When in discharge mode the DC/DC converters are all connected to the cell stack and cell balancing works in exactly the same way as above Lithium Ion implementation. Switch A is closed and switch B is open during charge mode. In discharge mode Switch A is open and Switch B is closed.

In an alternative embodiment the programmable logic can be programmed to operate internal heaters to warm the cells to enable additional energy release. The heaters deriving their power from the battery pack. This technique enables maximum energy to be released from the battery pack at low temperatures. The heaters may also operate in charge mode to increase charge acceptance of the battery pack thus enabling maximum energy storage. The programmable logic algorithms compensate for charge acceptance and charge release with cell temperature to allow accurate tracking of cell capacity.

In one preferred embodiment of the invention, Protection, SoC, SoH, Active Cell Balance Control, Charger Control, Communication Bus, Microprocessor, and Memory monitoring means are integrated onto a single Application Specific Integrated Circuit using CMOS, BiCMOS or BiPOLAR semiconductor process. All electronic power circuitry would be external to the Application Specific Integrated Circuit.

In addition all power electronic circuitry can be integrated onto the substrate as control, monitoring, acquisition, processing and communication.

Other embodiments make use of several integrated circuits and additional electronic circuitry.

The present invention allows the integration of all the above functional blocks onto a single integrated circuit in a way that will serve a wide application base. This single integrated circuit can then be embedded into the battery pack to remove all battery management from the host system and in doing so reduce manufacturing cost, increase battery capacity, increase battery life, and increase system reliability.

Improvements and modifications may be incorporated herein without deviating from the scope of the invention.

1. A battery management system for use with one or more cells comprising a battery, the battery management system comprising:
one or mote battery monitoring means; and
programmable logic; wherein the programmable logic is connected to the one or more battery monitoring means to modify its battery operation and report battery status.

2. A battery management system as claimed in claim 1 wherein, the battery monitoring means reports battery status through a communication bus to an external host.

3. A battery management system as claimed in claim 1 wherein the battery monitoring means is provided with data acquisition means to record battery performance parameters.

4. A battery management system as claimed in claim 1, wherein the programmable logic is configured to analyse data received from the one or mote battery monitoring means and to modify the operation of the battery in response to said data.

5. A battery management system as claimed in claim 3 wherein, the data acquisition means is placed across each cell of the battery to collect data from said cell.

6. A battery management system as claimed in claim 3 wherein the data acquisition means is configured to collect data from a plurality of cells.

7. A battery management system as claimed in claim 1, wherein, the programmable logic is configured to analyse physical data.

8. A battery management system as claimed in claim 1, wherein, the programmable logic is configured to analyse physical data relating to the effect of temperature on battery capacity and/or the effect of temperature on battery self discharge current.

9. A battery management system as claimed in claim 1, wherein, the programmable logic is configured to derive the actual state of charge at any operational temperature.

10. A battery management system as claimed in claim 1, wherein, the programmable logic contains one or more took-up tables and/or algorithms.

11. A battery management system as claimed in claim 1, wherein, the programmable logic comprises a digital microprocessor and digital memory.

12. A battery management system as claimed in claim 1, wherein, the programmable logic comprises a digital means of communication with internal and external systems and the ability to report battery status and provide external control of a battery.

13. A battery management system as claimed in claim 1, wherein, the programmable logic is embedded in the battery management system.

14. A battery management system as claimed in claim 1, wherein, the battery monitoring means comprises state of charge measurement means.

15. A battery management system as claimed in claim 1, wherein, the battery monitoring means comprises state of health measurement means.

16. A battery management system as claimed in claim 1, wherein, the battery monitoring means comprises battery protection means.

17. A battery management system as claimed in claim 1, wherein, the battery protection means comprises switching means to control current flow from a power source.

18. A battery management system as claimed in claim 1, wherein, the battery monitoring means comprises charging control means.

19. A battery management system as claimed in claim 1, wherein, the battery monitoring means comprises active cell balancing control means enabling transfer of energy from strong to weak cells.

20. A battery management system as claimed in claim 19 wherein, the active cell balancing control comprises a switched mode converter, attachable to a primary energy source and capable of moving energy from the primary energy source to one or more cells depending upon the respective energy requirements of the cells.

21. A battery management system as claimed in claim 1, wherein, the programmable logic is adapted to operate temperature control means.

22. A battery management system as claimed in claim 21 wherein, the temperature control means comprises heating means to warm the cells.

23. A battery management system as claimed in claim 19 wherein, the active cell balancing control meansoperates as an integral charger.

24. A battery management system as claimed in claim 19 wherein, the active cell balancing means operates as a sulphation removal system when used in a Pb (lead acid) battery stack.

25. A battery management system as claimed in claim 20 wherein, a Flyback topology can be used as a switched mode converter.

26. A battery management system as claimed in claim 25 wherein, the Flyback switched mode converter is provided with one or more synchronous output or secondary rectifiers.

27. A battery management system as claimed in claim 25 wherein, the Flyback switched mode converter is provided with one or more output or secondary rectifier diodes.

28. A battery management system as claimed in claim 1, wherein, a switched magnetic or capacitive converter may be configured to actively transfer energy from strong cells to weak cells within the battery pack.

29. A battery management system as claimed in claim 1, wherein, the battery management system is provided with self discharge current measurement means.

30. A battery management system as claimed in claim 29 wherein, the self discharge measurement means comprises a current oscillator which can be coupled to a battery when the battery is in sleep mode, the current oscillator having a temperature coefficient that corresponds to the temperature coefficient of the battery.

31. A battery management system as claimed in claim 1, wherein the battery management system is provided with means for disabling the battery during transit, said means being provided as an instruction from the programmable logic.

32. A battery management system as claimed in claim 1, wherein the battery management system is incorporated in an application specific integrated circuit.

33. A battery management system as claimed in claim 1, wherein the battery management system is incorporated in a discrete printed circuit board.

34. A battery pack containing a battery and a battery management system as claimed in claim 1, wherein the battery management system is embedded in the battery pack.
